(19) United States
(12) Patent Application Publication
(10) Pub. No.: US 2025/0031368 A1
(43) Pub. Date: Jan. 23, 2025

(54) SEMICONDUCTOR STRUCTURE AND FABRICATION METHOD THEREOF, MEMORY SYSTEM

(71) Applicant: Yangtze Memory Technologies Co., Ltd., Wuhan (CN)

(72) Inventors: Xiaoxin LIU, Wuhan (CN); Zongliang HUO, Wuhan (CN)

(21) Appl. No.: 18/389,717

(22) Filed: Dec. 19, 2023

(30) Foreign Application Priority Data
Jul. 21, 2023 (CN) 202310907266.3

(51) Int. Cl. H10B 43/27; H10B 41/27

(52) U.S. Cl. CPC H10B 43/27; H10B 41/27

(57) ABSTRACT

The present disclosure provides a semiconductor structure and a fabrication method thereof, and a memory system, relates to the technical field of semiconductor chip. The semiconductor structure includes a stack structure and a memory post. The stack structure includes gate insulation layers and gate layers stacked alternatively in the first direction. The memory post penetrates the stack structure in the first direction; the memory post includes a first channel structure, a second channel structure and an isolation section; the first channel structure and the second channel structure are disposed oppositely in the second direction that is perpendicular to the first direction; the isolation section is located between the first channel structure and the second channel structure and isolates the first channel structure and the second channel structure.

### CROSS-REFERENCE TO RELATED APPLICATIONS

This application claims priority to Chinese Patent Application No. 202310907266.3, filed on Jul. 21, 2023, which is hereby incorporated by reference in its entirety.

### TECHNICAL FIELD

The present disclosure relates to the field of semiconductor chip technology, in particular to a semiconductor structure and a fabrication method thereof, as well as a memory system.

### BACKGROUND

As the feature sizes of memory cells approach the lower limit of process, planar process and manufacturing techniques have become challenging and costly, resulting in storage density for 2D or planar NAND flashes approaching an upper limit.

In order to overcome limitations on 2D or planar NAND flashes, memories with three-dimensional structure (3D NAND) have been developed in the industry, which improve the storage density by arranging the memory cells on the substrate in three dimensions. However, three-dimensional memories still suffer the problem of increasing storage density.

### SUMMARY

Implementations of the present disclosure provide a semiconductor structure and a fabrication method thereof, and a memory system, aiming at increasing the storage density of the semiconductor structure.

In order to achieve the above-described object, implementations of the present disclosure adopt the following technical solutions.

On the one hand, there is provided a semiconductor structure. The semiconductor structure includes a stack structure and a memory post. The stack structure includes gate insulation layers and gate layers stacked alternatively in the first direction. The memory post penetrates the stack structure in the first direction; the memory post includes a first channel structure, a second channel structure and an isolation section; the first channel structure and the second channel structure are disposed oppositely in the second direction that is perpendicular to the first direction; the isolation section is located between the first channel structure and the second channel structure and isolates the first channel structure and the second channel structure.

By separating into the first channel structure and the second channel structure by the isolation section, the total number of the first channel structure and the second channel structure is larger in the present implementation, thereby increasing the storage density of the semiconductor structure. In each memory post, the provided isolation section can separate the first channel structure and the second channel structure, thereby improving the interference between the first channel structure and the second channel structure, such as improving the short-circuit problem between the first channel structure and the second channel structure.

In some implementations, each of the first channel structure and the second channel structure comprises a channel layer. The isolation section comprises two first isolation sections and one second isolation section; the two first isolation sections are disposed oppositely in a third direction that is perpendicular to the first direction and intersects the second direction; the second isolation section is located between: the two first isolation sections, the channel layer of the first channel structure and the channel layer of the second channel structure.

In some implementations, a material for the first isolation section and a material for the second isolation section are the same.

In some implementations, the channel layer of the first channel structure and the channel layer of the second channel structure comprise first end surfaces opposite to each other in the second direction, and the first isolation section covers the first end surfaces.

In some implementations, each of the first channel structure and the second channel structure further comprises a storage function layer located between the channel layer and the stack structure. The storage function layer of the first channel structure and the storage function layer of the second channel structure comprise second end surfaces opposite to each other in the second direction, and the first isolation section further covers the second end surfaces.

In some implementations, the storage function layer comprises: a tunneling layer, a storage layer and a blocking layer away from the channel layer. The first isolation section further covers the tunneling layer and the storage layer.

In some implementations, the size of the first isolation section in the second direction is greater than or equal to one fourth of the size of the memory post in the second direction and less than or equal to a half of the size of the memory post in the second direction.

In some implementations, a size of the first isolation section in the second direction is equal to one third of a size of the memory post in the second direction.

In some implementations, a surface perpendicular to the first direction is defined as a reference surface. Orthogonal projections of the first channel structure and the second channel structure on the reference surface are arc-like projections, and opening directions of the two arc-like projections are opposite to each other in the second direction.

In some implementations, the first channel structure and the second channel structure are disposed symmetrically in the second direction.

In some implementations, the number of the memory posts is plurality, the plurality of memory posts are successively arranged at intervals in a third direction that is perpendicular to the first direction and intersects the second direction. The semiconductor structure further comprises a separation section. The separation section comprises a plurality of sub-separation sections successively disposed at intervals in the third direction, the sub-separation sections penetrate the stack structure in the first direction and connect the isolation sections in two of the memory posts adjacent in the third direction.

In some implementations, a material for the separation section and a material for the isolation section are the same.

On the other hand, there is provided a fabrication method of a semiconductor structure. The fabrication method comprises: forming a stack structure comprising gate insulation layers and gate layers stacked alternatively in a first direction; and forming a memory post penetrating the stack structure in the first direction; the memory post comprising a first channel structure, a second channel structure and an isolation section; the first channel structure and the second channel structure being disposed oppositely in a second direction that is perpendicular to the first direction; the isolation section being located between the first channel structure and the second channel structure and isolating the first channel structure and the second channel structure.

In some implementations, forming the stack structure and forming the memory post comprise: forming a stacked-layer structure on the substrate, the stacked-layer structure comprising first film layers and second film layers stacked alternatively in a first direction; forming a channel hole penetrating the stacked-layer structure in the first direction; forming a storage function film and a channel film successively on an inner wall of the channel hole and filling a first material inside the channel film; forming a separating groove penetrating the stacked-layer structure in the first direction and extending in a third direction that is perpendicular to the first direction and intersects the second direction; the separating groove opening a part of the storage function film and exposing two target sections in the channel film that are opposite to each other in the third direction; and processing the target sections via the separating groove to obtain a first isolation section that is a part of the isolation section.

In some implementations, processing the target sections via the separating groove comprises subjecting the target sections to oxidization.

In some implementations, forming the separating groove comprises: disposing a mask plate on a side of the stacked-layer structure away from the substrate; wherein the mask plate has a plurality of hollowed-out regions which extend in the third direction and which are arranged in the second direction; and removing the stacked-layer structure and a part of the storage function film with each hollowed-out region to form the separating groove.

In some implementations, removing the stacked-layer structure and the part of the storage function film with each hollowed-out region to form the separating groove comprises: etching the stacked-layer structure and the part of the storage function film through each hollowed-out region with an etching solution in a wet etching process to form the separating groove; wherein an etch rate of the etching solution for the storage function film and the stacked-layer structure is greater than an etch rate of the etching solution for the channel film and the first material.

In some implementations, forming the stack structure and forming the memory post further comprises: removing the first material that comprises a compound of carbon atoms, silicon atoms and oxygen atoms, or an organic substance or a metal; filling a third material between: the two first isolation sections, the channel layer of the first channel structure and the channel layer of the second channel structure, to form a second isolation section; the third material comprising an oxide.

In some implementations, the first film layer is a gate insulating layer, the second film layer is a gate sacrificial layer, forming the stack structure and forming the memory post further comprises: replacing the gate sacrificial layer with the gate layer via the separating groove after processing the target section to obtain the stack structure.

In some implementations, after processing the target sections, replacing the gate sacrificial layer with the gate layer via the separating groove comprises: removing the gate sacrificial layer via the separating groove; filling a gate material via the separating groove to form the gate layer to obtain the stack structure; and removing the gate material in the separating groove such that a plurality of gate layers are separated.

In some implementations, forming the stack structure and forming the memory post further comprise: filling a second material in the separating groove to form a separation section.

In yet another aspect, there is provided a memory system. The memory system comprises the above-described semiconductor structure, and a controller coupled to the semiconductor structure.

In yet another aspect, there is provided an electronic apparatus comprising the memory system as described above.

It is appreciated that the beneficial effects that can be achieved by the fabrication method of the semiconductor structure, the memory system and the electronic apparatus provided in the above-described implementations of the present disclosure can be inferred with reference to the beneficial effects of the semiconductor structure described above, and will not be described again herein.

### BRIEF DESCRIPTION OF DRAWINGS

In order to explain the technical solutions in the present disclosure more clearly, accompanying drawings required in some implementations of the present disclosure will be described in brief below. It is obvious that the below described drawings are only drawings of some implementations of the present disclosure and other drawings may be obtained according to these drawings for those of ordinary skill in the art. Furthermore, accompanying drawings described below may be regarded as illustrative diagrams rather than limiting the practical sizes of products, practical flows of methods, practical timings of signals, etc., involved in implementations of the present disclosure.

FIG. 1 is a structure diagram of a memory system according to some implementations;

FIG. 2 is a structure diagram of a memory system according to other implementations;

FIG. 3 is a structure diagram of a 3D memory according to some implementations;

FIG. 4 is a top view of a semiconductor structure according to some implementations;

FIG. 5 is a diagram along line A-A in FIG. 4;

FIG. 6 is a partially enlarged view of region I in FIG. 4;

FIG. 7 is a structure diagram of a memory cell string according to some implementations;

FIG. 8 is an equivalent circuit diagram of the memory cell string shown in FIG. 7;

FIG. 9 is a structure diagram of a memory cell string provided according to other implementations;

FIG. 10 is an equivalent circuit diagram of the memory cell string shown in FIG. 9;

FIG. 11 is a structure diagram of another 3D memory according to some implementations;

FIG. 12 is a flowchart of a fabrication method of a semiconductor structure according to some implementations;

FIG. 13 is a flowchart of a fabrication method of another semiconductor structure according to some implementations; and

FIGS. 14-23 are process diagrams of a fabrication method of a semiconductor structure according to some implementations.

### DETAILED DESCRIPTION

The technical solution in implementations of the present disclosure will be described below clearly and completely with reference to accompanying drawings. However, it is obvious that the described implementations are only partial implementations rather than all implementations of the present disclosure. All other implementations obtained by one of ordinary skill in the art based on implementations provided in the present disclosure fall within the scope of the present disclosure.

In the description of the present disclosure, it is to be understood that terms “center”, “on”, “under”, “front”, “back”, “left”, “right”, “vertical”, “horizontal”, “top”, “bottom”, “inside”, “outside” etc. refer to the azimuth or position relationship based on what is shown in figures, which are only for the purpose of facilitating describing the present disclosure and simplifying description rather than indicating or implying that the mentioned devices or elements must have certain azimuth, must be constructed and operated in certain azimuth, and therefore are not constructed as limiting the present disclosure.

Unless otherwise stated in context, the term “include” will be interpreted in an open and containing sense, namely “contain but not limited to” throughout the description and claims. In the description of the specification, terms such as “one implementation”, “some implementations”, “example implementation”, “illustratively” or “some examples” are intended to indicate certain features, structures, materials or characteristics related to the implementation(s) or example(s) are included in at least one implementation or example of the present disclosure. The illustrative representation of the above terms do not necessarily refer to the same implementation or example. Furthermore, said certain features, structures, materials or characteristics may be included in any one or more implementations or examples in any suitable manner.

Hereinbelow, the terms “first”, “second” etc. are only used for the purpose of description and should not be understood to indicate or imply relative importance or to designate the number of the referenced technical features implicitly. Therefore, a feature qualified by “first” or “second” may include one or more instances of the feature explicitly or implicitly. In the description of implementations of the present disclosure, “a plurality of” means two or more unless otherwise specified.

While describing some implementations, expressions such as “couple” and “connect” as well as their extensions might be used. For example, when describing some implementations, the term “connect” may be used to indicate that two or more components have direct physical contact or electrical contact with each other. As another example, when describing some implementations, the term “couple” may be used to indicate that two or more components have direct physical contact or electrical contact. However, the term “couple” may also indicate there is no direct contact between two or more components, but they still cooperate or interact with each other. Implementations disclosed herein are not necessarily limited to the contents provided herein.

“At least one of A, B and C” and “at least one of A, B or C” have the same meaning and both include the following combinations of A, B and C: only A; only B; only C; a combination of A and B; a combination of A and C; a combination of B and C; and a combination of A, B and C.

“A and/or B” includes the following three combinations: only A, only B and combination of A and B.

The use of “adapted to” or “configured to” in the present description implies open and inclusive wording but not excluding apparatuses adapted to or configured to execute additional tasks or operations.

In addition, the use of “based on” implies open and inclusive wording, since a process, a operation, a computation or other acts “based on” one or more said conditions or values may be based on additional conditions or values other than said value in practice.

As used herein, “about”, “generally” or “approximately” includes the stated value and the average value in the acceptable deviation range of a certain value, wherein said acceptable deviation range is determined by those of ordinary skill in the art considering the measurements under discussion and errors, namely limitations of the measurement system, related to measurements of a certain quantity.

In contents of the present disclosure, the meanings of “on”, “over” and “above” should be interpreted in the broadest manner such that “on” not only means “directly on” something but also includes the meaning of “on” something with an intermediate feature or a layer therebetween, and that “over” or “above” not only means the meaning of “over” or “above” something, but also include the meaning it is “above” or “over” something with no intermediate feature or layer therebetween (i.e., directly on something).

Example implementations are described herein with reference to sectional views and/or plan views as ideal illustrative drawings. In the drawings, thicknesses of layers and regions are enlarged for clarity. Therefore, it is possible to envision shape variations with respect to drawings due to manufacturing techniques and/or tolerances. Accordingly, example implementations should not be interpreted as limiting the shapes of regions shown herein, but including shape deviations caused by for example manufacturing. For example, an etched region shown as rectangular generally has curved features. Therefore, regions shown in drawings are illustrate in nature, and their shapes are not intended to show practical shapes of regions of a device and not intended to limit the scope of example implementations.

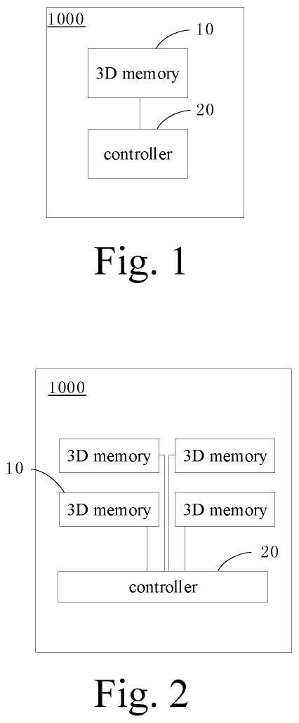

FIG. 1 is a structure diagram of a memory system according to some implementations. FIG. 2 is a structure diagram of a memory system according to other implementations.

Referring to FIGS. 1 and 2, some implementations of the present disclosure provide a memory system 1000. The memory system 1000 may be integrated into various storage devices such as being included in the same package (such as Universal Flash Storage (UFS)) or Embedded Multi Media Card (eMMC). That is, the memory system 1000 can be applied to and packaged into different types of electronic products such as a mobile phone (e.g., a handset), a desktop computer, a tablet, a notebook computer, a server, an on-vehicle device, a gaming console, a printer, a positioning device, a wearable device, a smart sensor, a mobile power source, a virtual reality (VR) device, an argument reality (AR) device, or any other suitable electronic devices having a storage therein.

The memory system 1000 includes a controller 20 and a 3D memory 10, and the controller 20 is coupled to the 3D memory 10. The controller 20 is configured to control the 3D memory 10 to store data.

Illustratively, referring to FIG. 1, the memory system 1000 includes a controller 20 and one 3D memory 10 and may be integrated into a memory card. The memory card includes any one of a PC card (PCMCIA), a Compact Flash (CF) card, a Smart Media (SM) card, a memory stick, a Multimedia Card (MMC), a Secure Digital Memory Card (SD) or a UFS.

Illustratively, referring to FIG. 2, the memory system 1000 includes a controller 20 and a plurality of 3D memories 10 and is integrated into a solid state drive (SSD).

In the memory system 1000, in some implementations, the controller 20 is configured to operate in low duty cycle environment, such as SD cards, CF cards, Universal Serial Bus (USB) flash drives, or other media used in electronic devices such as personal calculators, digital cameras and mobile phones. In other implementations, the controller 20 is configured to operate in high duty cycle environment SSDs or eMMCs that are used as data stores and enterprise memory arrays of the mobile devices such as smart phones, tablet computers and notebook computers.

Illustratively, the controller 20 may be configured to manage the data stored in 3D memory 10 and communicate with an external device (such as a host). Illustratively, the controller 20 may be also configured to control operations of the 3D memory 10, such as read, erase, and program operations. Illustratively, the controller 20 may also be configured to manage various functions with respect to the data stored or to be stored in the 3D memory 10 including at least one of bad-block management, garbage collection, logical-to-physical address conversion, and wear leveling. Illustratively, the controller 20 is further configured to process error correction codes with respect to the data read from or written to the 3D memory 10.

Of course, any other suitable functions may be performed by the controller 20 as well, for example, formatting the 3D memory 10. For example, the controller 20 may communicate with an external device such as a host via at least one of various interface protocols.

It is to be noted that the interface protocols include at least one of USB protocol, MMC protocol, peripheral component interconnection (PCI) protocol, PCI-express (PCI-E) protocol, advanced technology attachment (ATA) protocol, serial-ATA protocol, parallel-ATA protocol, small computer small interface (SCSI) protocol, enhanced small disk interface (ESDI) protocol, integrated drive electronics (IDE) protocol and Firewire protocol.

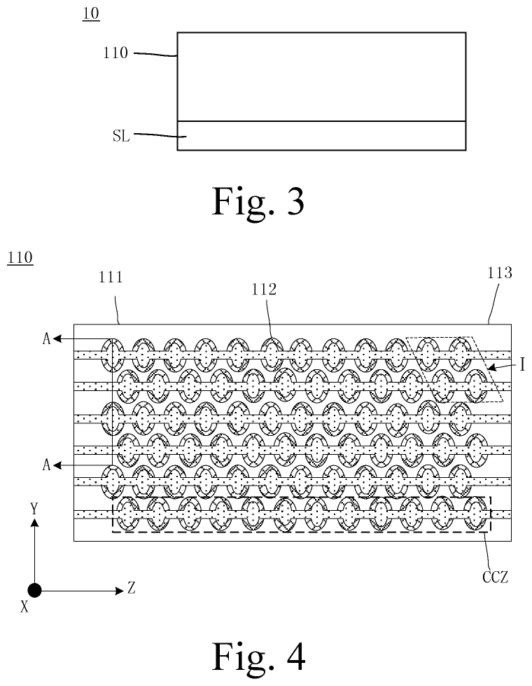

FIG. 3 is a structure diagram of a 3D memory 10 according to some implementations.

Referring to FIG. 3, the 3D memory 10 may include a semiconductor structure 110 and a source layer SL. The source layer SL is coupled with the semiconductor structure 110.

The source layer SL may include semiconductor materials such as single crystalline silicon, single crystalline germanium, III-V compound semiconductor materials, II-V compound semiconductor materials and other suitable semiconductor materials. The source layer SL may be partially or completely doped. Illustratively, the source layer SL may include a doped region doped with a p-type dopant. The source layer SL may also include a non-doped region.

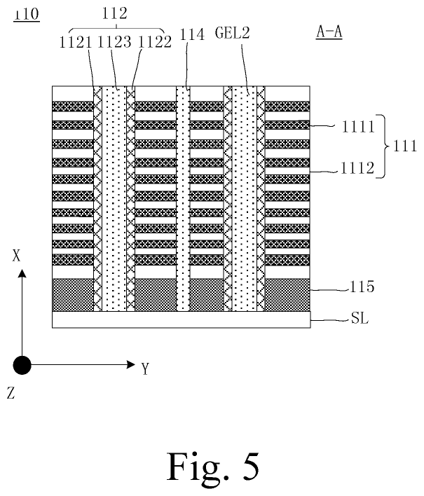

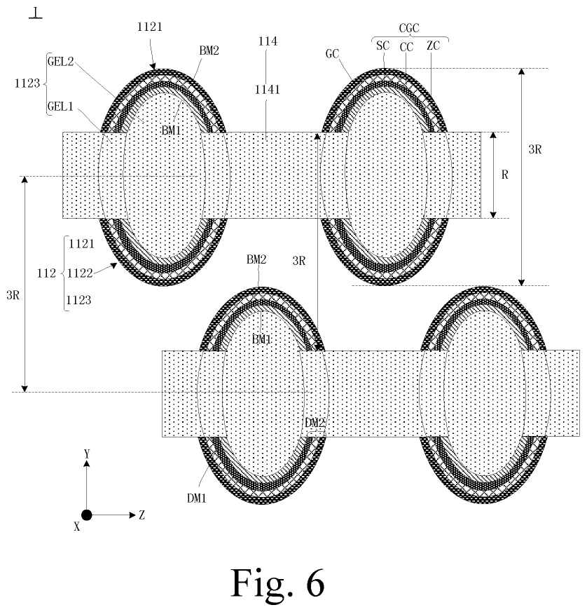

FIG. 4 is a top view of a semiconductor structure 110 according to some implementations. FIG. 5 is a diagram along line A-A in FIG. 4. FIG. 6 is a partially enlarged view of region I in FIG. 4.

Referring to FIGS. 4-6, the semiconductor structure 110 may include a stack structure 111. The stack structure 111 includes gate insulation layers 1112 and gate layers 1111 stacked alternatively in the first direction X.

The first direction X is the direction in which the plurality of gate insulation layers 1112 and the plurality of gate layers 1111 are stacked alternatively. That is, the first direction X is the up/down direction shown in FIG. 5. The third direction Z is perpendicular to the first direction X and intersects (e.g., perpendicularly) the second direction Y. The third direction Z is perpendicular to the second direction Y. Therefore, the first direction X, the second direction Y and the third direction Z may constitute a three-dimensional coordinate system.

It is to be noted that the first direction X shown in all drawings herein may be understood as the arrow direction of the first direction X shown in FIG. 4 or the opposite direction of the arrow direction of the first direction X shown in FIG. 4. The third direction Z and the second direction Y in all drawings may be understood with reference to the above-described first direction X.

The stack structure 111 includes a plurality of gate layers 1111 stacked and gate insulating layers 1112 disposed between every two adjacent gate layers 1111. In addition, a gate insulating layer 1112 may be disposed on the top gate layer 1111. A gate insulating layer 1112 may also be disposed under the bottom gate layer 1111. Each gate layer 1111 may include a plurality of gate lines.

The material for the gate insulating layer 1112 may include an insulating material such as one or a combination of more than one of silicon oxide, silicon nitride and high dielectric constant insulating material, or may include other suitable materials. The gate layer 1111 may include conductive materials, which include, but not limited to, one or any combination of more than one of tungsten (W), cobalt (Co), copper (Cu), aluminum (Al), polysilicon, doped silicon and silicide. In some implementations, each gate layer 1111 may be a metal layer such as a tungsten layer. In other implementations, each gate layer 1111 may be a doped polysilicon layer.

In some examples, the semiconductor structure 110 may further include a substrate 115 that refers to a material layer upon which subsequent layers may be added. Subsequent layers added on top of the substrate 115 may be patterned or may remain unpatterned. For example, the stack structure 111 may be disposed on the substrate 115 and the substrate 115 itself may be patterned.

In some examples, the substrate 115 may be partially or completely doped. Then, the substrate 115 may serve as the source layer SL. Accordingly, the substrate 115 may include at least one of various semiconductor materials such as amorphous silicon, polysilicon, single crystalline silicon, single crystalline germanium, III-V compound semiconductor material or II-VI compound semiconductor material, for example, may include at least one of various semiconductor materials such as silicon, germanium, gallium arsenide or indium phosphide.

As shown in FIG. 5, in an implementation of the present disclosure, the substrate 115 is located between the stack structure 111 and the source layer SL, and the stack structure 111, the substrate 115 and the source layer SL are stacked in turn in the first direction X. Accordingly, the substrate 115 may be made of non-conductive materials such as glass, plastics or sapphire wafer.

Referring again to FIGS. 4-6, the semiconductor structure 110 in the implementation of the present disclosure may include a plurality of channel holes CH that penetrate the stack structure 111 in the first direction X. Memory posts 112 may be disposed in at least partial channel holes CH, and penetrate the stack structure 111 in the first direction X.

A memory post 112 includes a first channel structure 1121, a second channel structure 1122 and an isolation section 1123. The first channel structure 1121 and the second channel structure 1122 are disposed oppositely in the second direction Y. The isolation section 1123 is located between the first channel structure 1121 and the second channel structure 1122 that are disposed oppositely. Then, the second direction Y may be understood as a straight line passing the isolation section 1123.

As shown in FIG. 6, each of the first channel structure 1121 and the second channel structure 1122 includes a channel layer GC and a storage function layer CGC. The storage function layer CGC is located between the channel layer GC and the stack structure 111. The material for the channel layer GC may include the semiconductor material such as one or a combination of more than one of amorphous silicon, polysilicon or single crystalline silicon. The channel layer GC may be electrically connected with the source layer SL.

The storage function layer CGC may include a tunneling layer SC, a storage layer CC and a blocking layer ZC away from the channel layer GC. The material for the tunneling layer SC may include insulating materials such as one or a combination of more than one of silicon oxide, silicon nitride or silicon oxynitride. Electrons and holes in the channel layer GC may tunnel to the storage layer CC through the tunneling layer SC. The storage layer CC may be configured to store charges. One or more memory cells in a memory cell string may be operated by storing charges to the storage layer CC or removing charges from the storage function layer CGC. The material for the storage layer CC may include one or a combination of more than one of silicon oxide, silicon oxynitride or silicon. The blocking layer ZC may be configured to prevent charges stored in the storage layer CC from leaking to the gate layer 1111. The material for the blocking layer ZC may include insulating materials. For example, the material for the blocking layer ZC may include one or a combination of more than one of silicon oxide, silicon nitride or silicon oxynitride.

In some examples, both the first channel structure 1121 and the second channel structure 1122 extend into the substrate 115, thereby realizing electrical connection between the first channel structure 1121, the second channel structure 1122 and the source layer SL. For example, as shown in FIG. 5, the bottoms of the first channel structure 1121 and the second channel structure 1122 may be flush with the lower surface of the substrate 115 (away from the surface of the stack structure 111). As another example, the bottoms of the first channel structure 1121 and the second channel structure 1122 do not penetrate the lower surface of the substrate 115. That is, a part of the substrate 115 is located under the first channel structure 1121 and the second channel structure 1122.

Referring again to FIGS. 4-6, the isolation section 1123 is made of insulating material that may be silicon oxide, silicon nitride or silicon oxynitride. The provision of the isolation section 1123 is to isolate the channel layer GC and the storage function layer CGC in the first channel structure 1121 and the second channel structure 1122, and improve the interference between the first channel structure 1121 and the second channel structure 1122 (for example, improving the short circuit problem between the first channel structure 1121 and the second channel structure 1122).

In some examples, the semiconductor structure 110 may further include a separation section 114 including sub-separation sections 1141 contacting either side of the isolation section 1123 in the third direction Z respectively; that is, the isolation section 1123 may be disposed between two sub-separation sections 1141 arranged at intervals in the third direction Z.

Sub-separation sections 1141 in the separation section 114 extend in the third direction Z and penetrate the stack structure 111 in the first direction X. The material for the separation section 114 includes insulating material that may be silicon oxide, silicon nitride or silicon oxynitride. The isolation section 1123 and the separation section 114 may be of the same material or different materials.

The provision of the separation section 114 is to separate the stack structure 111 into two parts corresponding to the first channel structure 1121 and the second channel structure 1122, wherein in the stack structure 111 on the same side of the separation section 114 and the isolation section 1123 as the first channel structure 1121, the gate layer 1111 may be configured as a gate line coupled with the first channel structure 1121; and in the stack structure 111 on the same side of the separation section 114 and the isolation section 1123 as the second channel structure 1122, the gate layer 1111 may be configured as a gate line coupled with the second channel structure 1122.

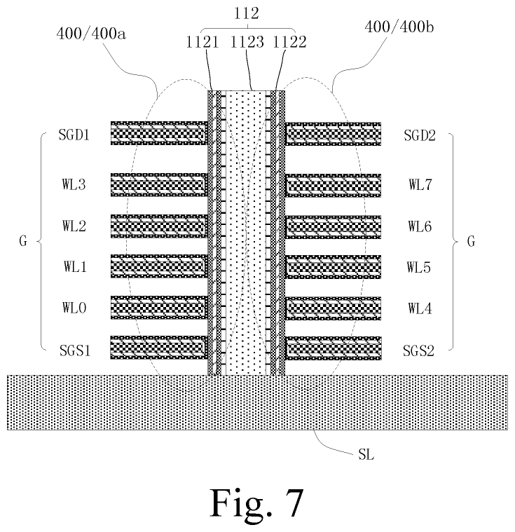

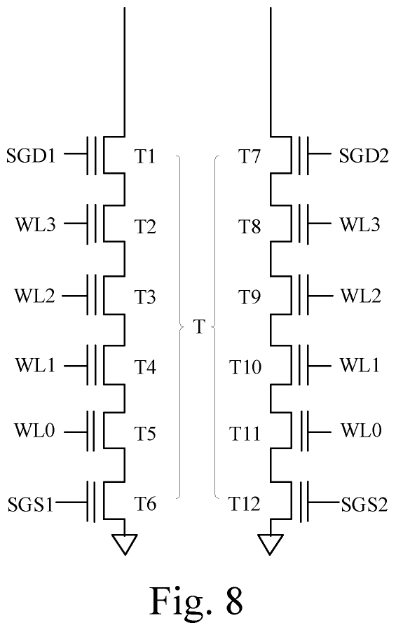

FIG. 7 is a structure diagram of a memory cell string according to some implementations; and FIG. 8 is an equivalent circuit diagram of the memory cell string shown in FIG. 7. As shown in FIGS. 7 and 8, in the semiconductor structure 110 provided in the implementations of the present disclosure, each memory post 112 and a plurality of gate lines G (gate layer 1111) surrounding the memory post 112 may form two memory cell transistor string 400 (referred to herein as “memory cell string”, e.g., NAND memory cell string), namely the first memory cell string 400a and the second memory cell string 400b. The source layer SL may be coupled with the source of the memory cell string 400 (including the first memory cell string 400a and the second memory cell string 400b).

As shown in FIGS. 7 and 8, the first memory cell string 400a includes a plurality of transistors T formed by the first channel structure 1121 and the plurality of gate lines G. One transistor T (such as T1-T6 in FIG. 8) may be configured as one memory cell. These transistors T are connected together to form the first memory cell string 400a. A transistor T (such as each transistor T) may be formed by the first channel structure 1121 and a gate line G surrounding the first channel structure 1121. The gate line G is configured to control the turn-on state of the transistor.

It is to be noted that the number of transistors in the first memory cell string 400a in FIGS. 7-8 is only illustrative. The first memory cell string 400a in the 3D memory provided in implementations of the present disclosure may also include other number of transistors, such as 4, 16, 32 and 64.

In some implementations, in the third direction Z, the bottom one of the plurality of gate lines G (such as the one closest to the source layer SL in the plurality of gate lines G) may be configured as a source select gate SGS1, and the source select gate SGS1 is configured to control the turn-on state of the transistor T6 and in turn control the turn-on state of the source in the first memory cell string 400a. The top one of the plurality of gate lines G (such as the one farthest from the source layer SL in the plurality of gate lines G) may be configured as the drain select gate SGD1, and the drain select gate SGD1 is configured to control the turn-on state of the transistor T1 and in turn control the turn-on state of the drain in the first memory cell string 400a. The gate line in the middle of the plurality of gate lines G may be configured a plurality of word lines WL including for example word line WL0, word line WL1, word line WL2 and word line WL3. It is possible to implement data writing, reading and erasing of the respective memory cells such as the transistor T in the first memory cell string 400a by writing different voltages on the word lines WL.

Referring again to FIGS. 7 and 8, the second memory cell string 400b includes a plurality of transistors T formed by the second channel structure 1122 and the plurality of gate lines G. One transistor T (such as T7-T12 in FIG. 8) may be configured as one memory cell. These transistors T are connected together to form the second memory cell string 400b. A transistor T (such as each transistor T) may be formed by the second channel structure 1122 and a gate line G surrounding the second channel structure 1122. The gate line G is configured to control the turn-on state of the transistor.

It is to be noted that the number of transistors in the second memory cell string 400b in FIGS. 7-8 is only illustrative. The second memory cell string 400b in the 3D memory provided in the implementations of the present disclosure may also include other number of transistors, such as 4, 16, 32 and 64.

In some implementations, in the third direction Z, the bottom one of the plurality of gate lines G (such as the one closest to the source layer SL in the plurality of gate lines G) may be configured as the source select gate SGS2, and the source select gate SGS2 is configured to control the turn-on state of the transistor T12 and in turn control the turn-on state of the source in the second memory cell string 400b. The top one of the plurality of gate lines G (such as the one farthest from the source layer SL in the plurality of gate lines G) may be configured as the drain select gate SGD2, and the drain select gate SGD2 is configured to control the turn-on state of the transistor T7 and in turn control the turn-on state of the drain in the second memory cell string 400b. The gate line in the middle of the plurality of gate lines G may be configured a plurality of word lines WL including for example word line WL4, word line WL5, word line WL6 and word line WL7. It is possible to implement data writing, reading and erasing of the respective memory cells such as the transistor T in the second memory cell string 400b by writing different voltages on the word lines WL.

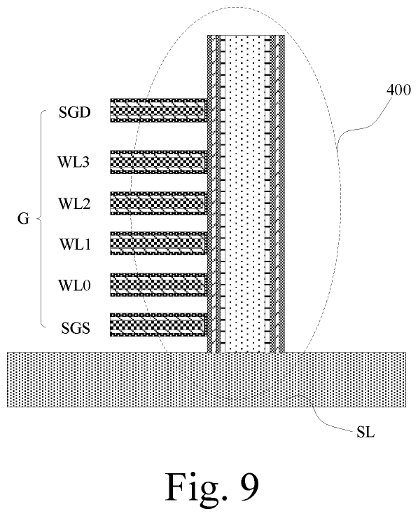

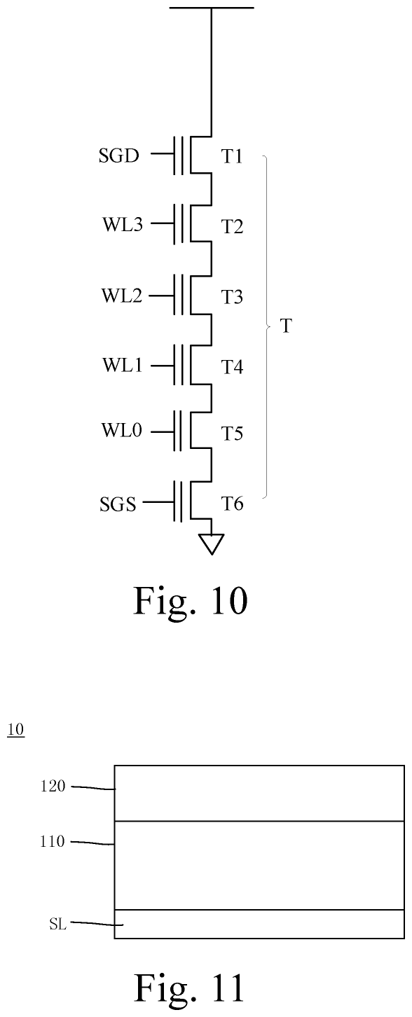

An implementation of the present disclosure provides another semiconductor structure at the same time, which has a structure at the channel hole as shown in FIGS. 9 and 10. As can be seen in FIGS. 9 and 10, in the semiconductor structure provided in the implementation, only one memory cell string 400 can be formed at the location of one channel hole.

As can be seen by comparison, as compared to the semiconductor structure in which only one memory cell string 400 can be formed in one channel hole (such as the scheme shown in FIGS. 9 and 10), adopting the semiconductor structure 110 in which a memory post 112 (including the first channel structure 1121, the second channel structure 1122 and the isolation section 1123) is provided in a channel hole CH, it is possible to form more memory cell strings 400 in the same number of channel holes CH, thereby increasing the storage density of the semiconductor structure 110.

In some examples, as shown in FIGS. 4 and 6, the first channel structure 1121 and the second channel structure 1122 may be disposed symmetrically in the second direction Y; that is, the surface perpendicular to the first direction X is defined as the reference surface 113. For example, the reference surface 113 may be the plane in which the gate layer 1111 or the gate insulating layer 1112 is located. For example, the reference surface 113 may also be the YZ plane formed by the second direction Y and the third direction Z. The orthogonal projections of the first channel structure 1121 and the second channel structure 1122 on the reference surface 113 have the same area. With such a design, it is in favor of the fabrication of the first channel structure 1121 and the second channel structure 1122.

In some examples, the number of the memory posts 112 may be plurality. Referring again to FIG. 4, the plurality of memory posts 112 may be divided into a plurality of memory post groups CCZ successively arranged at intervals in the second direction Y. Each memory post group CCZ may include a plurality of memory posts 112 successively arranged at intervals in the third direction Z. Memory posts 112 in adjacent two memory post groups CCZ may be disposed in a stagger manner.

In a possible implementation, the size of adjacent two memory post groups CCZ in the second direction may be equal to the size of the memory post 112 in the second direction Y. For example, as shown in FIG. 6, the spacing between adjacent two memory post groups CCZ in the second direction Y is 3R, and the size of the memory post 112 in the second direction Y is also 3R.

Referring again to FIG. 6, in some examples, in each memory post 112, the isolation section 1123 may include two first isolation sections GEL1 and one second isolation section GEL2. The two first isolation sections GEL1 are disposed oppositely in the third direction Z. Then, the third direction Z may be understood as a straight line passing the second isolation section GEL2 and perpendicular to both the first direction X and the second direction Y. The second isolation section GEL2 is located between the two first isolation sections GEL1, the channel layer GC of the first channel structure 1121 and the channel layer GC of the second channel structure 1122.

In some examples, both the channel layer GC of the first channel structure 1121 and the channel layer GC of the second channel structure 1122 include first surfaces BM1 opposite to each other in the second direction Y. At this time, the second isolation section GEL2 may be located between the two first isolation sections GEL1, the first surface BM1 of the first channel structure 1121 and the first surface BM1 of the second channel structure 1122.

The material for the first isolation section GEL1 includes insulating material that may be silicon oxide, silicon nitride or silicon oxynitride. The material for the second isolation section GEL2 includes insulating material for which the relevant description of material for the first isolation section GEL1 may be referred to. Illustratively, the material for the first isolation section GEL1 is the same as the material for the second isolation section GEL2 such that the process operations and devices may be reduced, which facilitates reducing costs. For example, both the material for the first isolation section GEL1 and the material for the second isolation section GEL2 may include silicon oxide. The price of silicon oxide is low among insulating materials such that a cost may be reduced. Illustratively again, the material for the first isolation section GEL1 and the material for the second isolation section GEL2 may be different and the insulating performance of the first isolation section GEL1 is greater than that of the second isolation section GEL2. For example, the material for the first isolation section GEL1 include silicon nitride and the material for the second isolation section GEL2 include silicon oxide.

Both the channel layer GC of the first channel structure 1121 and the channel layer GC of the second channel structure 1122 include first end surfaces DM1 opposite to each other in the second direction Y. Both the storage function layer CGC of the first channel structure 1121 and the storage function layer CGC of the second channel structure 1122 include second end surfaces DM2 opposite to each other in the second direction Y (the second end surface DM2 may be understood as the end surface constituted of the end surface of the blocking layer ZC, the end surface of the tunneling layer SC and the end surface of the storage layer CC).

The first isolation section GEL1 may cover the first end surface DM1 and may also cover parts or entirety of the second end surface DM2. With such a design, it is possible to protect (at least in part) the storage function layer CGC by covering the second end surface DM2, thereby improving the problem of influencing and damaging the storage function layer CGC in subsequent processes to guarantee the storage performance of the memory cells.

For example, in case that the first isolation section GEL1 covers the first end surface DM1, the first isolation section GEL1 may further cover the entirety of the second end surface DM2 which may be understood as the end surface constituted of the end surface of the blocking layer ZC, the end surface of the tunneling layer SC and the end surface of the storage layer CC.

As another example, in case that the first isolation section GEL1 covers the first end surface DM1, the first isolation section GEL1 may further cover a part of the second end surface DM2. Illustratively, the first isolation section GEL1 only covers a part of the second end surface DM2 for the tunneling layer SC and the storage layer CC and a part of the second end surface DM2 for the blocking layer ZC is not covered by the isolation section.

In case that the first isolation section GEL1 covers a part of the second end surface DM2, the other part of the second end surface DM2 that is not covered by the first isolation section GEL1 may be covered by the separation section 114. Illustratively, the first isolation section GEL1 covers the part of the second end surface DM2 for the tunneling layer SC and the storage layer CC; the other part of the second end surface DM2 for the blocking layer ZC may be covered by the separation section 114; in this case, the part of the second end surface DM2 may be understood as the end surface constituted of the end surface of the tunneling layer SC and the end surface of the storage layer CC, and the other part of the second end surface DM2 may be understood as the end surface of the blocking layer ZC.

In other implementations, the first isolation section GEL1 covers the first end surface DM1 and does not cover the second end surface DM2 that may be covered by the separation section 114.

In some implementations, the size of the first isolation section GEL1 in the second direction Y may be greater than or equal to a quarter of the size of the memory post 112 in the second direction Y, and less than or equal to a half of the size of the memory post 112 in the second direction Y. Illustratively, the size of the first isolation section GEL1 in the second direction Y may be greater than or equal to one third of the size of the memory post 112 in the second direction Y, and less than or equal to a half of the size of the memory post 112 in the second direction Y. In some examples, the size of the first isolation section GEL1 in the second direction Y may be equal to one fourth, one third or a half of the size of the memory post 112 in the second direction Y. For example, as shown in FIG. 6, the size of the memory post 112 in the second direction Y is 3R, the size of the first isolation section GEL1 in the second direction Y is R; and the size of the first isolation section GEL1 in the second direction Y is equal to one third of the size of the memory post 112 in the second direction Y.

With such a design, given that the process requirements for manufacturing the memory posts 112 are satisfied, it is possible to improve the uniformity of layout of the first channel structure 1121, the second channel structure 1122 and the isolation section 1123 in the memory posts 112 in the channel hole CH, thereby facilitating the fabrication of the memory posts 112.

In some examples, the size of the separation section 114 in the second direction Y may be equal to the size of the first isolation section GEL1 in the second direction Y.

In some implementations, both the orthogonal projections of the first channel structure 1121 and the second channel structure 1122 on the reference surface 113 may be arc-like projections.

Both the storage function layer CGC of the first channel structure 1121 and the storage function layer CGC of the second channel structure 1122 include second end surfaces DM2 opposite to each other in the second direction Y (the second end surface DM2 may be understood as the surface of the blocking layer ZC and contacts the stack structure 111). At this time, the arc-like projection may be the orthogonal projections of the first surface BM1, the first end surface DM1, the second end surface DM2, the second surface BM2, the second end surface DM2 and the first end surface DM1 connected end to end successively on the reference surface 113. The first surface BM1 and the second surface BM2 are arcuate surfaces and the first end surface DM1 and the second end surface DM2 may be planes.

The opening directions for the two arc-like projections may be opposing in the second direction Y. In some examples, the opening directions for the two arc-like projections are disposed symmetrically in the second direction Y. The opening of the arc-like projection may be the shape of the orthogonal projection of the first surface BM1 on the reference surface 113.

In some implementations, the separation section 114 in the semiconductor structure 110 may include a plurality of sub-separation sections 1141 disposed at intervals in turn in the third direction Z and penetrating the stack structure 111 in the first direction X. Each sub-separation section 1141 connects isolation sections 1123 in the two memory posts 112 adjacent in the third direction Z. For example, each sub-separation section 1141 connects the first isolation sections GEL1 in the two memory posts 112 adjacent in the third direction Z.

In some examples, the material for the separation section 114 may be the same as the material for the isolation section 1123. That is, the material for the separation section 114, the material for the first isolation section GEL1 and the material for the second isolation section GEL2 are all the same. For example, both the material for the separation section 114 and the material for the isolation section 1123 may include silicon oxide. In other examples, the material for the separation section 114 may be different from the material for the isolation section 1123. That is, the material for the first isolation section GEL1 is same as the material for the second isolation section GEL2 and different from the material for the separation section 114. For example, the material for the separation section 114 may include silicon nitride, and the material for the isolation section 1123 (i.e., the first isolation section GEL1 and the second isolation section GEL2) may include silicon oxide.

In some implementations, the semiconductor structure 110 may further include an array interconnection layer. The array interconnection layer may be coupled with the memory cell strings in the semiconductor structure 110.

FIG. 11 is a structure diagram of another 3D memory 10 according to some implementations.

In some implementations, the 3D memory 10 may further include a peripheral device 120. The semiconductor structure 110 is coupled with the peripheral device 120 that may be disposed on a side of the semiconductor structure 100 away from the source layer SL. A controller 20 may be coupled with the peripheral device 120.

The peripheral device 120 may include a peripheral circuit configured to control and sense the semiconductor structure 110 (for example, it may be an array device). The peripheral circuit may be at least one of any suitable digital, analog or hybrid signal control and sense circuit for supporting the operation (or work) of the array device, including, but not limited to a page buffer, a decoder (such as a row decoder and a column decoder), a sense amplifier, a driver (such as a word line driver), a charge pump, a current or voltage reference, or any active or inactive components of a circuit such as a transistor, a diode, a resistor or a capacitor. The peripheral circuit may further include any other circuits compatible with advanced logic processes, including a logic circuit such as a processor and a programmable logic device (PLD) or a memory circuit such as a static random access memory (SRAM).

In some examples, the peripheral circuit may include at least one (for example, one, or a plurality of) transistor.

Illustratively, the peripheral device 120 may further include a peripheral interconnection layer coupled with the peripheral circuit for transmitting an electric signal between the peripheral circuit and the peripheral interconnection layer. For example, the peripheral interconnection layer may be coupled with a transistor for transmitting the electric signal between the transistor and the peripheral interconnection layer.

The peripheral interconnection layer may be coupled with the array interconnection layer such that the semiconductor structure 110 may be coupled with the peripheral device 120. In an example, since the peripheral interconnection layer is coupled with the array interconnection layer, the peripheral circuit in the peripheral device 120 may be coupled with the memory cell strings in the semiconductor structure 110 for transmitting the electrical signal between the peripheral circuit and the memory cell strings.

In some possible implementations, there may be provided a bonding interface between the peripheral interconnection layer and the array interconnection layer by which the peripheral interconnection layer and the array interconnection layer may be bonded and coupled with each other.

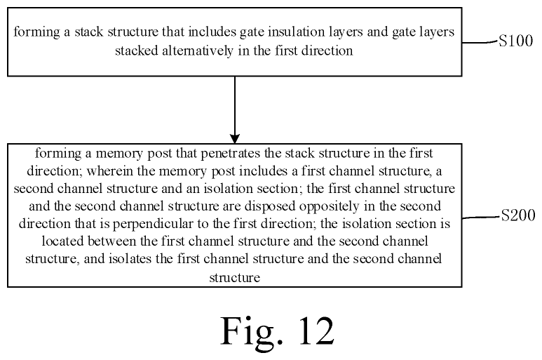

FIG. 12 is a flowchart of a fabrication method of a semiconductor structure according to some implementations.

An implementation of the present disclosure further provides a fabrication method of a semiconductor structure. Referring to FIG. 12, the fabrication method includes operation S100 and operation S200.

Operation S100: forming a stack structure 111 that includes gate insulation layers 1112 and gate layers 1111 stacked alternatively in the first direction X.

Operation S200: forming a memory post 112 that penetrates the stack structure 111 in the first direction X; wherein the memory post 112 includes a first channel structure 1121, a second channel structure 1122 and an isolation section 1123; the first channel structure 1121 and the second channel structure 1122 are disposed oppositely in the second direction Y that is perpendicular to the first direction X; the isolation section 1123 is located between the first channel structure 1121 and the second channel structure 1122, and the isolation section 1123 isolates the first channel structure 1121 and the second channel structure 1122.

It is to be noted that relevant description of the semiconductor structure 110 may be referred to for the description of operation S100 and operation S200. Relevant description of the effects of the above-described semiconductor structure 110 may be referred to for the effects of the semiconductor structure formed by operation S100 and operation S200.

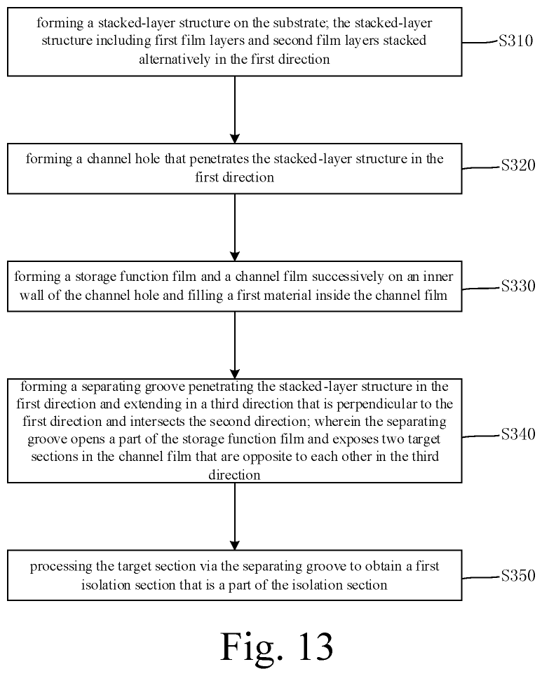

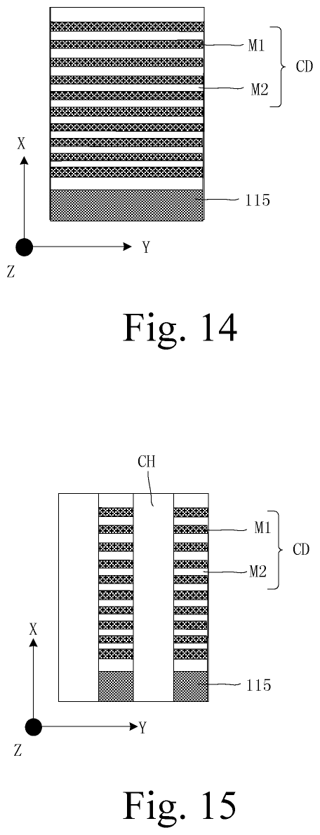

FIG. 13 is a flowchart of a fabrication method of another semiconductor structure according to some implementations. FIGS. 14-23 are process diagrams of a fabrication method of a semiconductor structure according to some implementations.

Referring to FIG. 13, operation S100 and operation S200 may include: operation S310-operation S350.

Operation S310: referring to FIG. 14, forming a stacked-layer structure CD on the substrate 115. The stacked-layer structure CD includes a film layer M1 and a second film layer M2 stacked alternatively in the first direction X.

In some examples, the first film layer M1 may be a gate layer 1111, and the second film layer M2 may be a gate insulating layer 1112, which form the stack structure 111. Relevant description of the stack structure 111 in the above-described semiconductor structure 110 may be referred to for the stack structure 111.

In other examples, the first film layer M1 may be a gate sacrificial layer, and the second film layer M2 may be a gate insulating layer 1112.

The gate sacrificial layer may include a material with high etch selection ratio with respect to the gate insulating layer 1112. In some examples, each gate insulating layer 1112 includes a silicon oxide layer, and each gate sacrificial layer includes a silicon nitride layer. That is, a plurality of silicon nitride layers and a plurality of silicon oxide layers may be deposited alternatively on the substrate 115.

The gate insulation layers 1112 and the gate sacrificial layers may be formed by one or more film deposition processes including, but not limited to a chemical vapor phase deposition (CVD), a physical vapor deposition (PVD), an atomic layer deposition (ALD) or any combination thereof. The silicon oxide and silicon nitride are a material pair with high etching selection ratio. In an example, the etching selection ratio between the silicon oxide and the silicon nitride is greater than 10. Of course, the gate sacrificial layer and the gate insulating layer 1112 may also be other material pair with high etching selection ratio, which is only for illustration rather than limitation. For example, relevant description of the material for the gate insulating layer 1112 in the semiconductor structure 110 may also be referred to for the material for the gate insulating layer 1112.

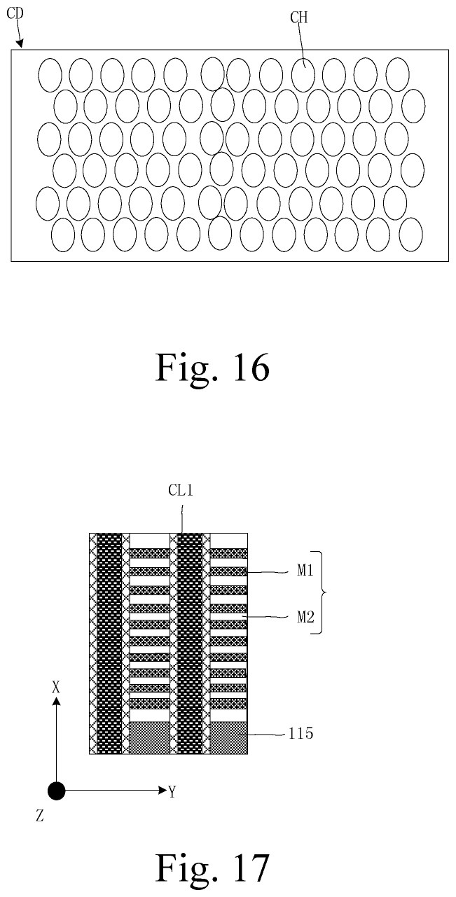

Operation S320: referring to FIGS. 15 and 16, forming a channel hole CH that penetrates the stacked-layer structure CD in the first direction X.

For example, it is possible to define the pattern of the channel hole CH in the photoresist with the photolithography technology and form the channel hole CH penetrating the stacked-layer structure CD by at least one of the wet etching or the dry etching. For example, the etching process may be deep reactive ion etching (DRIE). Relevant description of the location relationship of the memory post 112 in the semiconductor structure 110 may be referred to for the location relationship of the channel hole CH. The orthogonal projection of the channel hole CH on the reference surface 113 may be regular shapes such as oval or circle, may also be irregular shapes approximate to regular shapes such as oval or circle.

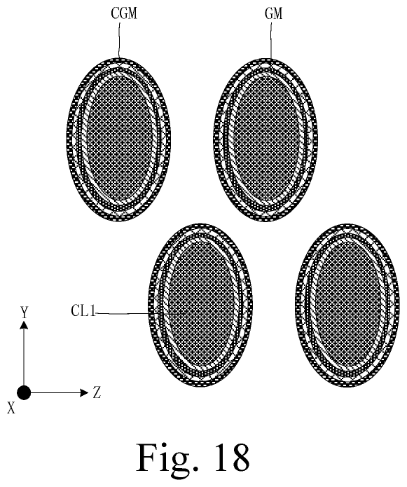

Operation S330: referring to FIGS. 17 and 18, forming a storage function film CGM and a channel film GM successively on the inner wall of the channel hole CH and filling a first material CL1 inside the channel film GM.

In some examples, in case that the first film layer M1 is a gate layer 1111, the second film layer M2 is a gate insulating layer 1112; or in case that the first film layer M1 is a gate insulating layer 1112 and the second film layer M2 is a gate sacrificial layer, the first material CL1 may include a compound of carbon atoms, silicon atoms and oxygen atoms, or an organic substance or a metal. For example, the first material CL1 may include SOC. The metal may be an elemental metal, and for example may be copper, iron, aluminum, silver, etc.; or may be a metal alloy such as alloy of the above-described elemental metals.

The relevant description of the storage function layer CGC in the above-described semiconductor structure 110 may be referred to for the material for the storage function film CGM. The relevant description of the channel layer GC in the above-described semiconductor structure 110 may be referred to for the material for the channel film GM.

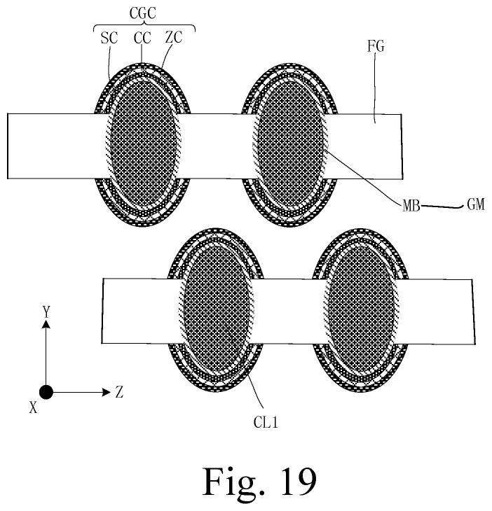

Operation S340: referring to FIG. 19, forming a separating groove FG penetrating the stacked-layer structure CD in the first direction X and extending in the third direction Z that is perpendicular to the first direction X and intersects the second direction Y; wherein the separating groove FG opens a part of the storage function film CGM and exposes two target sections MB opposite to each other in the third direction Z in the channel film GM.

In some implementations of the semiconductor structure and the fabrication method thereof, the array device includes a gate line slit for at least replacing the gate sacrificial layer with the gate layer. While in the present implementation, the separating groove FG may be formed to remove a part of the storage function layer CGM in one channel hole CH, and the remaining storage function layer CGM is the storage function layer CGC for the first channel structure 1121 and the storage function layer CGC for the second channel structure 1122. In addition, it is also possible to remove the gate sacrificial layer by the formed separating groove FG and form the gate layer by the separating groove FG. Therefore, as compared to the scheme in which the gate layer is made with the gate line slit, the separating groove FG in the present implementation may be configured to form the first channel structure and the second channel structure, and further to replace the gate sacrificial layer with the gate layer.

The two target sections MB may be understood as two parts of the channel film GM exposed by the separating groove FG in one channel hole CH. The parts in the channel film GM other than the two target sections MB are the channel layer GC of the first channel structure 1121 and the channel layer GC of the second channel structure 1122 respectively.

In an example, the operation of forming the separating groove FG includes: disposing a mask plate on a side of the stacked-layer structure CD away from the substrate 115; wherein the mask plate has a plurality of hollowed-out regions which extend in the third direction Z and are arranged in the second direction Y. The stacked-layer structure CD and the part of storage function film CGM are removed with each hollowed-out region to form the separating groove FG.

In some examples, the orthogonal projection of the hollowed-out region on the reference surface 113 may include regular shapes such as rectangle or square, may also be irregular shapes approximate to regular shapes such as rectangle or square. It is to be noted that relevant description of arranging the plurality of memory post groups CCZ at intervals in the second direction Y in the semiconductor structure 110 may be referred to for the arrangement of the plurality of hollowed-out regions.

In some examples, the stacked-layer structure CD and the part of the storage function film CGM are etched through each hollowed-out region with the etching solution in the wet etching process to form the separating groove FG.

The etch rate of the etching solution for the storage function film CGM and the stacked-layer structure CD is greater than the etch rate of the etching solution for the channel film GM and the first material CL1. Therefore, the etching solution may be prevented from etching the channel film GM and the first material CL1.

For example, a ratio of the etch rate of the etching solution for the storage function film CGM and the stacked-layer structure CD over the etch rate of the etching solution for the channel film GM and the first material CL1 is greater than 10 (for example, equal to 10, equal to 15, equal to 20, equal to 30 etc.), which are only for illustration rather than limitation.

The size of each of the separating groove FG, the part of the storage function film CGM, the target section MB, the hollowed-out region in the second direction Y is equal to the size of the first isolation section GEL1 in the semiconductor structure 110 in the second direction Y. For example, the size of each of the separating groove FG, the part of the storage function film CGM, the target section MB, the hollowed-out region in the second direction Y is equal to one third of the size of the memory post 112 in the second direction Y.

In case that the size of the separating groove FG in the second direction Y is equal to one fourth of the size of the memory post 112 in the second direction Y, the etching solution can just etch through the stacked-layer structure CD to form the separating groove FG such that the remaining storage function film CGM has a larger area, resulting in a larger area of the formed first channel structure 1121 and the second channel structure 1122. In case that the size of the separating groove FG in the second direction Y is equal to a half of the size of the memory post 112 in the second direction Y, the etching solution can remove the gate sacrificial layer quickly and form the gate layer 1111 quickly.

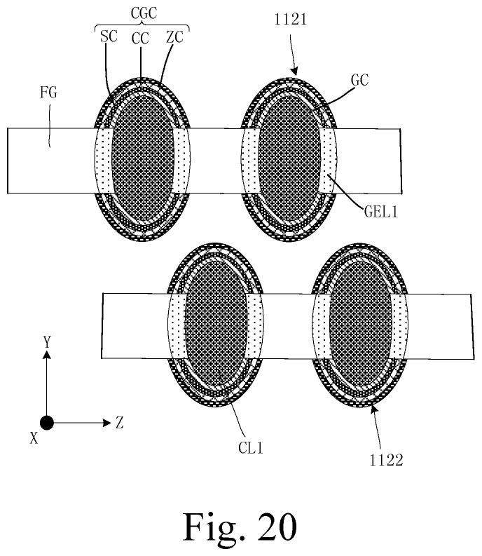

Operation S350: referring to FIG. 20, processing the target section MB via the separating groove FG to obtain the first isolation section GEL1 that is a part of the isolation section 1123.

In some examples, the target section MB is subjected to oxidation to form an oxide. For example, the material for the channel film GM may include a single crystalline silicon, then the material for the target section MB may also include the single crystalline silicon, and the target section MB is oxidized to form a silicon oxide.

In other examples, the target section MB is removed (by etching for example with a wet etching process or a dry etching process) and an oxide (e.g., silicon oxide) is filled to obtain the first isolation section GEL1.

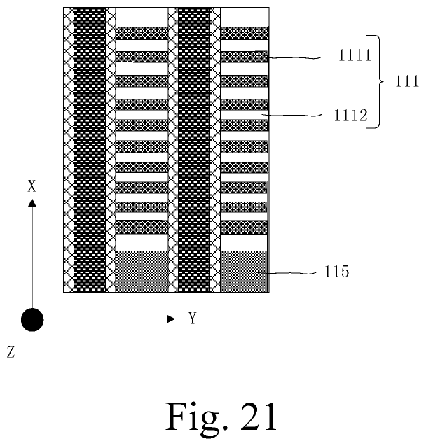

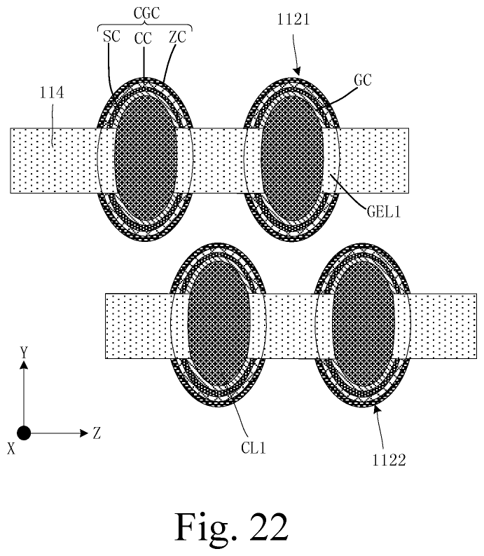

In some implementations, the fabrication method further includes: referring to FIG. 21, replacing the gate sacrificial layer with the gate layer 1111 via the separating groove FG after processing the target section MB to obtain the stack structure 111 in case that the first film layer M1 is the gate insulating layer 1112 and the second film layer M2 is the gate sacrificial layer. Referring to FIG. 22, the second material is filled in the separating groove FG to form the separation section 114.

Relevant description of the material for the separation section 114 in the semiconductor structure 110 may be referred to for the selection of the second material.

In an example, the gate sacrificial layer is removed via the separating groove FG. The gate material is filled via the separating groove FG to form the gate layer 1111, obtaining the stack structure 111. The gate material located in the separating groove FG is removed such that the plurality of gate layers 1111 are separated, thereby avoiding electrical connection between the gate layers 1111.

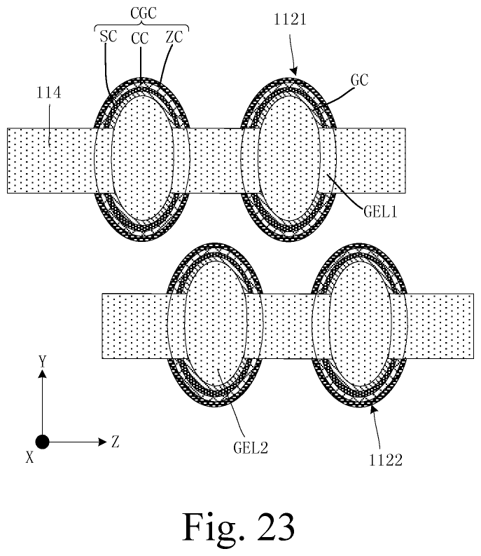

In some implementations, the fabrication method further includes: removing the first material CL1 that may include a compound of carbon atoms, silicon atoms and oxygen atoms, or an organic substance or a metal. Referring to FIG. 23, the third material is filled between the two first isolation sections GEL1, the channel layer GC of the first channel structure 1121 and the channel layer GC of the second channel structure 1122 to form the second isolation section GEL2. The third material may include oxides such as silicon oxide.

It is to be noted that after the two target sections MB of the channel film is processed, two first isolation sections GEL1 are obtained, and the unprocessed channel film GM are the channel layer GC for the first channel structure 1121 and the channel layer GC for the second channel structure 1122 respectively. At this time, the first material CL1 being located in the channel film GM may be replaced with the first material CL1 being located between the two first isolation sections GEL1, the channel layer GC of the first channel structure 1121 and the channel layer GC of the second channel structure 1122. Accordingly, it is possible to fill the third material between the two first isolation sections GEL1, the channel layer GC of the first channel structure 1121 and the channel layer GC of the second channel structure 1122.

The semiconductor structure and the method thereof provided in implementations of the present disclosure may increase storage density and reduce costs.

What have been described above are only implementations of the present disclosure. The scope of the present disclosure is not limited thereto. Variations and substitutions that can be easily thought of by any one skilled in the art in the technical scope disclosed by the present disclosure should be encompassed in the scope of the present disclosure. Therefore, the scope of the present disclosure should be determined by the scope of the claims.

What is claimed is:

1. A semiconductor structure, comprising:
a stack structure comprising gate insulation layers and gate layers stacked alternatively in a first direction; and
a memory post penetrating the stack structure in the first direction; the memory post comprising a first channel structure, a second channel structure and an isolation section; the first channel structure and the second channel structure being disposed oppositely in a second direction that is perpendicular to the first direction;
the isolation section being located between the first channel structure and the second channel structure and isolating the first channel structure and the second channel structure.

2. The semiconductor structure of claim 1, wherein
each of the first channel structure and the second channel structure comprises a channel layer; and
the isolation section comprises two first isolation sections and one second isolation section; the two first isolation sections are disposed oppositely in a third direction that is perpendicular to the first direction and intersects the second direction; the second isolation section is located between: the two first isolation sections, the channel layer of the first channel structure and the channel layer of the second channel structure.

3. The semiconductor structure of claim 2, wherein
a material for the first isolation section and a material for the second isolation section are same.

4. The semiconductor structure of claim 2, wherein
the channel layer of the first channel structure and the channel layer of the second channel structure comprise first end surfaces opposite to each other in the second direction, and the first isolation section covers the first end surfaces.

5. The semiconductor structure of claim 4, wherein
each of the first channel structure and the second channel structure further comprises a storage function layer located between the channel layer and the stack structure; and
the storage function layer of the first channel structure and the storage function layer of the second channel structure comprise second end surfaces opposite to each other in the second direction, and the first isolation section further covers the second end surfaces.

6. The semiconductor structure of claim 5, wherein
the storage function layer comprises: a tunneling layer, a storage layer and a blocking layer away from the channel layer; and
the first isolation section further covers the tunneling layer and the storage layer.

7. The semiconductor structure of claim 2, wherein
a size of the first isolation section in the second direction is greater than or equal to one fourth of a size of the memory post in the second direction and less than or equal to a half of a size of the memory post in the second direction.

8. The semiconductor structure of claim 7, wherein
the size of the first isolation section in the second direction is equal to one third of the size of the memory post in the second direction.

9. The semiconductor structure of claim 1, wherein
a surface perpendicular to the first direction is defined as a reference surface; and
orthogonal projections of the first channel structure and the second channel structure on the reference surface are arc-like projections and opening directions of the two arc-like projections are opposite to each other in the second direction.

10. The semiconductor structure of claim 1, wherein
the first channel structure and the second channel structure are disposed symmetrically.

11. The semiconductor structure of claim 1, wherein a number of the memory posts is plurality, the plurality of memory posts are successively arranged at intervals in a third direction that is perpendicular to the first direction and intersects the second direction;
the semiconductor structure further comprises:
a separation section comprising a plurality of sub-separation sections successively disposed at intervals in the third direction, the sub-separation sections penetrate the stack structure in the first direction and connect the isolation sections in two of the memory posts adjacent in the third direction.

12. The semiconductor structure of claim 11, wherein
a material for the separation section and a material for the isolation section are same.

13. A fabrication method of a semiconductor structure, comprising:
forming a stack structure comprising gate insulation layers and gate layers stacked alternatively in a first direction; and
forming a memory post penetrating the stack structure in the first direction; the memory post comprising a first channel structure, a second channel structure and an isolation section; the first channel structure and the second channel structure being disposed oppositely in a second direction that is perpendicular to the first direction; the isolation section being located between the first channel structure and the second channel structure and isolating the first channel structure and the second channel structure.

14. The fabrication method of claim 13, wherein the forming the stack structure and the forming the memory post comprise:
forming a stacked-layer structure on a substrate, the stacked-layer structure comprising first film layers and second film layers stacked alternatively in the first direction;
forming a channel hole penetrating the stacked-layer structure in the first direction;
forming a storage function film and a channel film successively on an inner wall of the channel hole and filling a first material inside the channel film;
forming a separating groove penetrating the stacked-layer structure in the first direction and extending in a third direction that is perpendicular to the first direction and intersects the second direction; the separating groove opening a part of the storage function film and exposing two target sections in the channel film that are opposite to each other in the third direction; and
processing the target sections via the separating groove to obtain a first isolation section that is a part of the isolation section.

15. The fabrication method of claim 14, wherein
the processing the target sections via the separating groove comprises subjecting the target sections to oxidization.

16. The fabrication method of claim 14, wherein the forming the separating groove comprises:
disposing a mask plate on a side of the stacked-layer structure away from the substrate; the mask plate having a plurality of hollowed-out regions; the plurality of hollowed-out regions extending in the third direction and being arranged in the second direction; and
removing the stacked-layer structure and the part of the storage function film with each hollowed-out region to form the separating groove.

17. The fabrication method of claim 16, wherein the removing the stacked-layer structure and the part of the storage function film with each hollowed-out region to form the separating groove comprises:
etching the stacked-layer structure and the part of the storage function film through each hollowed-out region with an etching solution in a wet etching process to form the separating groove;
wherein an etch rate of the etching solution for the storage function film and the stacked-layer structure is greater than an etch rate of the etching solution for the channel film and the first material.

18. The fabrication method of claim 14, wherein the forming the stack structure and the forming the memory post further comprise:
removing the first material that comprises a compound of carbon atoms, silicon atoms and oxygen atoms, or an organic substance or a metal; and
filling a third material between: the two first isolation sections, a channel layer of the first channel structure and a channel layer of the second channel structure, to form a second isolation section; the third material comprising an oxide.

19. The fabrication method of claim 14, wherein
the first film layer is a gate insulating layer, the second film layer is a gate sacrificial layer, and the forming the stack structure and the forming the memory post further comprise:
after processing the target sections, replacing the gate sacrificial layer with the gate layer via the separating groove to obtain the stack structure.

20. A memory system, comprising:
a semiconductor structure, comprising:
a stack structure comprising gate insulation layers and gate layers stacked alternatively in a first direction; and
a memory post penetrating the stack structure in the first direction; the memory post comprising a first channel structure, a second channel structure and an isolation section; the first channel structure and the second channel structure being disposed oppositely in a second direction that is perpendicular to the first direction; the isolation section being located between the first channel structure and the second channel structure and isolating the first channel structure and the second channel structure; and
a controller coupled to the semiconductor structure.
